(19) United States
(12) Patent Application Publication
(10) Pub. No.: US 2026/0314302 A1
(43) Pub. Date: Oct. 8, 2026

(54) BONDING APPARATUS, BONDING SYSTEM, AND BONDING METHOD

(71) Applicant: Tokyo Electron Limited, Tokyo (JP)

(72) Inventors: Yousuke MINE, Kikuchi-gun, Kumamoto (JP); Yasutaka MIZOMOTO, Kikuchi-gun, Kumamoto (JP)

(73) Assignee: Tokyo Electron Limited, Tokyo (JP)

(21) Appl. No.: 19/480,410

(22) PCT Filed: Apr. 18, 2024
(86) PCT No.: PCT/JP2024/015435

§ 371 Date: Oct. 31, 2025

(30) Foreign Application Priority Data
May 2, 2023 (JP) 2023-076345

(51) Int. Cl. H10P 72/00; H10P 10/00; H10P 72/50

(52) U.S. Cl. CPC H10P 72/0446; H10P 10/12; H10P 72/53

(57) ABSTRACT

A bonding apparatus includes a chip carrier holder; a substrate holder; a first chip transfer mechanism; and a second chip transfer. The chip carrier holder holds a chip carrier from above the chip carrier in a state that multiple chips are held by the chip carrier and a bonding surface of each of the multiple chips faces downwards. The substrate holder holds a substrate from below the substrate in a state that a bonding surface of the substrate faces upwards. The first chip transfer mechanism receives the chip from the chip carrier and transfers the chip with the bonding surface of the chip facing downwards. The second chip transfer mechanism receives the chip from the first chip transfer mechanism and bonds the chip to the substrate with the bonding surface of the chip facing downwards.

### TECHNICAL FIELD

The various aspects and embodiments described herein pertain generally to a bonding apparatus, a bonding system, and a bonding method.

### BACKGROUND

A chip mounting system described in Patent Document 1 includes a chip supply device, a bonding device, a surface processing device, a carry-in/out section, and a transfer section (see paragraph [0225] of Patent Document 1). The chip supply device supplies multiple chips individually. The chips are attached to a tape covering an opening of a frame, and are pushed upwards one by one and turned upside down one by one (see paragraph [0251] of Patent Document 1). The bonding device mounts the chips supplied from the chip supply device on a substrate.

### PRIOR ART DOCUMENT

Patent Document 1: Japanese Patent No. 6337400

### DISCLOSURE OF THE INVENTION

### Problems to Be Solved by the Invention

Exemplary embodiments provide a technique capable of suppressing the particle generation from the chip transfer mechanism that transfers a chip.

### Means for Solving the Problems

In an exemplary embodiment, a bonding apparatus includes a chip carrier holder; a substrate holder; a first chip transfer mechanism; and a second chip transfer. The chip carrier holder holds a chip carrier from above the chip carrier in a state that multiple chips are held by the chip carrier and a bonding surface of each of the multiple chips faces downwards. The substrate holder holds a substrate from below the substrate in a state that a bonding surface of the substrate faces upwards. The first chip transfer mechanism receives the chip from the chip carrier and transfers the chip with the bonding surface of the chip facing downwards. The second chip transfer mechanism receives the chip from the first chip transfer mechanism and bonds the chip to the substrate with the bonding surface of the chip facing downwards.

### Effect of the Invention

According to the exemplary embodiments, it is possible to suppress the particle generation from the chip transfer mechanism that transfers the chip.

### BRIEF DESCRIPTION OF THE DRAWINGS

FIG. 1 is a plan view schematically illustrating a bonding system according to an exemplary embodiment.

FIG. 2 is a flowchart illustrating a bonding method according to the exemplary embodiment.

FIG. 3 is a cross sectional view illustrating an example of a first chip carrier and a chip.

FIG. 4 is a cross sectional view illustrating an example of a second chip carrier.

FIG. 5 is a cross sectional view illustrating an example of the second chip carrier and the chip.

FIG. 6 is a cross sectional view illustrating an example of a substrate.

FIG. 7 is a cross sectional view illustrating an example of a chip-attached substrate.

FIG. 8 is a cross sectional view illustrating an example of an operation of a chip arranging device.

FIG. 9 is a cross sectional view illustrating an example of electrostatic attraction.

FIG. 10 is a cross sectional view illustrating an example of an operation of a bonding apparatus.

FIG. 11 is a cross sectional view illustrating the example of the operation following that shown in FIG. 10.

FIG. 12 is a plan view illustrating an example of a movement range of a chip carrier holder and a movement range of a substrate holder in the bonding apparatus.

FIG. 13 is a plan view illustrating a modification example of FIG. 12.

FIG. 14 is a cross sectional view illustrating an example of the chip carrier holder in the bonding apparatus.

FIG. 15 is a bottom view illustrating the example of the chip carrier holder in the bonding apparatus.

FIG. 16 is a cross sectional view illustrating an example of an attracting operation.

FIG. 17 is a cross sectional view illustrating an example of a separating operation.

FIG. 18 is a cross sectional view illustrating a modification example of FIG. 17.

### DETAILED DESCRIPTION

Hereinafter, exemplary embodiments of the present disclosure will be explained with reference to the accompanying drawings. In the various drawings, same or corresponding parts will be assigned same reference numerals, and redundant descriptions thereof will be omitted. In the present specification, the X-axis direction, the Y-axis direction, and the Z-axis direction are orthogonal to each other. The X-axis and Y-axis directions are horizontal directions, whereas the Z-axis direction is a vertical direction.

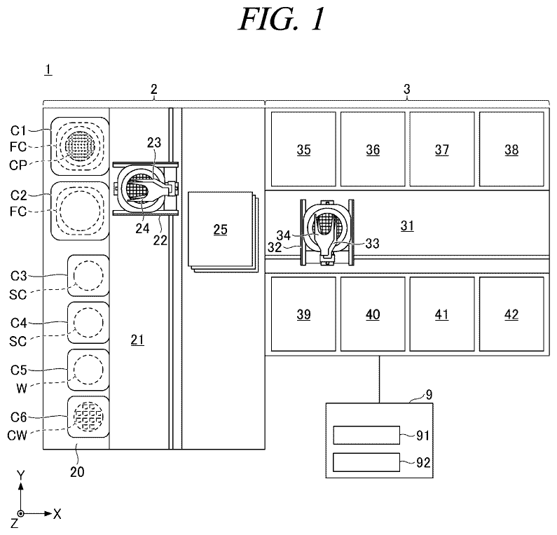

Below, referring to FIG. 1 to FIG. 11, a bonding system 1 according to an exemplary embodiment will be described. As shown in FIG. 7, the bonding system 1 manufactures a chip-attached substrate CW by bonding chips CP to a substrate W. The chip-attached substrate CW includes the substrate W and the multiple chips CP bonded to the substrate W.

The chip CP has a base substrate S1, and a device D1 formed on the base substrate S1. The base substrate S1 is, by way of non-limiting example, a silicon wafer, a compound semiconductor wafer, or a glass substrate. The device D1 includes a semiconductor element, a circuit, a terminal, and the like. The device D1 is formed on a bonding surface CPa of the chip CP.

The substrate W has a base substrate S2, and a plurality of devices D2 formed on the base substrate S2. The base substrate S2 is, by way of non-limiting example, a silicon wafer, a compound semiconductor wafer, or a glass substrate. The devices D2 include a semiconductor element, a circuit, a terminal, and the like. The device D2 is formed on a bonding surface Wa of the substrate W.

The device D1 of the chip CP and the device D2 of the substrate W are electrically connected. Although not shown, a plurality of devices D1 may be electrically connected to a single device D2. Here, the plurality of devices D1 may have different functions, i.e., different electric circuits. Further, the device D1 of one chip CP may be electrically connected to the device D2 of the substrate W via the device D1 of another chip CP.

As shown in FIG. 1, the bonding system 1 includes a carry-in/out station 2, a processing station 3, and a control circuit 9. The carry-in/out station 2 and the processing station 3 are arranged in this order from the negative X-axis side toward the positive X-axis side.

The carry-in/out station 2 is equipped with a placement table 20. Cassettes C1 to C6 are placed on the placement table 20. The cassette C1 accommodates a multiple number of chips CP held by a first chip carrier FC. The cassette C2 accommodates the first chip carrier FC after being used from which at least some of the chips CP have been removed. The cassettes C3 and C4 accommodate a second chip carrier SC. The cassette C5 accommodates the substrate W before being bonded to the chips CP. The cassette C6 accommodates the chip-attached substrate CW.

As shown in FIG. 3, the first chip carrier FC has a tape TP to which the chips CP are attached, and a frame FR to which an outer periphery of the tape TP is attached. The multiple number of chips CP are arranged in an opening of the frame R. The multiple number of chips CP are obtained by, for example, dicing a substrate in a state where the substrate is attached to the tape TP. The bonding surface CPa of each chip CP is protected by a protective film PF before the substrate is diced. The protective film PF is disposed on the opposite side from the tape TP with the chip CP therebetween. The protective film is removed before the chip CP is bonded to the substrate W.

The second chip carrier SC holds the multiple number of chips CP separated from the first chip carrier FC, as illustrated in FIG. 5. The second chip carrier SC is, for example, an electrostatic carrier. The electrostatic carrier electrostatically attracts the chips CP. The electrostatic carrier may electrostatically attract the chips CP and may also vacuum-attract them. Even after an electrostatic attracting force is lost, the chips CP can be continuously held by a vacuum attracting force. Furthermore, the second chip carrier SC does not have to be an electrostatic carrier, as will be described in detail later.

In the present exemplary embodiment, the second chip carrier SC holds the multiple number of chips CP having the same function, but may also hold the multiple number of chips CP having different functions. In the latter case, a plurality of first chip carriers FC are prepared for individual functions of the chips CP. The multiple number of chips CP with the different functions may be transferred from the plurality of first chip carriers FC onto the single second chip carrier SC.

The chip CP is transferred from the first chip carrier FC onto the second chip carrier SC to remove the protective film PF from the chip CP and modify the bonding surface CPa of the chip CP before the chip CP is bonded to the substrate W. This is to suppress the tape TP of the first chip carrier FC from being damaged when modifying the bonding surface CPa. Details of the second chip carrier SC will be described later.

As illustrated in FIG. 1, the carry-in/out station 2 is equipped with a transfer section 21, a first chip carrier transfer arm 22, a second chip carrier transfer arm 23, and a substrate transfer arm 24. Hereinafter, the first chip carrier transfer arm 22, the second chip carrier transfer arm 23, and the substrate transfer arm 24 may be collectively referred to as transfer arms 22 to 24.

The transfer section 21 is adjacent to the placement table 20. The transfer arms 22 to 24 hold and transfer the first chip carrier FC, the second chip carrier SC, and the substrate W in the transfer section 21, respectively. Each of the transfer arms 22 to 24 is configured to be movable in horizontal directions (both in the X-axis and Y-axis directions) and a vertical direction, and pivotable around a vertical axis.

The transfer arms 22 to 24 and a non-illustrated driver that moves or rotates the transfer arms 22 to 24 constitute a transfer device. The transfer arms 22 to 24 may be mounted on one and the same Y-axis slider as shown in FIG. 1 and moved simultaneously in the Y-axis direction, or may be mounted on different Y-axis sliders and moved independently in the Y-axis direction. The transfer arms 22 to 24 are arranged at different heights.

The carry-in/out station 2 is provided with a transition device 25 on the opposite side from the placement table 20 with the transfer section 21 therebetween. The transition device 25 is provided between the transfer section 21 of the carry-in/out station 2 and a transfer section 31 of the processing station 3, and relays the first chip carrier FC, the second chip carrier SC, or the substrate W between them. A plurality of such transition devices 25 may be stacked in multiple layers in the Z-axis direction.

The processing station 3 is equipped with the transfer section 31, a first chip carrier transfer arm 32, a second chip carrier transfer arm 33, and a substrate transfer arm 34. Hereinafter, the first chip carrier transfer arm 32, the second chip carrier transfer arm 33, and the substrate transfer arm 34 may be collectively referred to as transfer arms 32 to 34.

The transfer section 31 extends in the X-axis direction. The transfer arms 32 to 34 hold and transfer the first chip carrier FC, the second chip carrier SC, and the substrate W in the transfer section 31, respectively. Each of the transfer arms 32 to 34 is configured to be movable in horizontal directions (both in the X-axis and Y-axis directions) and a vertical direction, and pivotable around a vertical axis.

The transfer arms 32 to 34 and a non-illustrated driver that moves or rotates the transfer arms 32 to 34 constitute a transfer device. The transfer arms 32 to 34 may be mounted on one and the same X-axis slider as shown in FIG. 1 and moved in the X-axis direction simultaneously, or may be mounted on different X-axis sliders and moved independently in the X-axis direction. The transfer arms 32 to 34 are arranged at different heights.

The processing station 3 includes a chip arranging apparatus 35, a cleaning apparatus 36, a first activating apparatus 37, a first hydrophilizing apparatus 38, an inverting apparatus 39, a second activating apparatus 40, a second hydrophilizing apparatus 41, and a bonding apparatus 42. These apparatuses 35 to 42 are adjacent to the transfer section 31 and are respectively arranged on the positive Y-axis side or the negative Y-axis side of the transfer section 31.

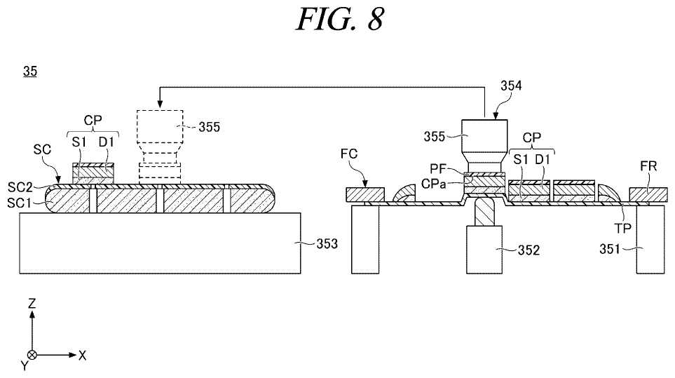

As shown in FIG. 8, the chip arranging apparatus 35 transfers the chip CP from the first chip carrier FC onto the second chip carrier SC. Thus, the damage to the tape TP of the first chip carrier FC can be avoided when modifying the bonding surface CPa. Details of this chip arranging apparatus 35 will be explained later.

The cleaning apparatus 36 removes the protective film PF from the chip CP with the chip CP being held by the second chip carrier SC. In addition, the cleaning apparatus 36 cleans the bonding surface CPa of the chip CP. This improves a processing quality of the bonding surface CPa to be performed thereafter.

The first activating apparatus 37 activates the bonding surface CPa of the chip CP with the chip CP being held by the second chip carrier SC. The first activating apparatus 37 is, by way of example, a plasma processing apparatus. For example, in the first activating apparatus 37, an oxygen gas, which is a processing gas, is excited into plasma under a compressed pressure to be ionized. By irradiating the bonding surface CPa of the chip CP with oxygen ions, the bonding surface CPa of the chip CP is activated. The processing gas is not limited to the oxygen gas, and may be, by way of example, a nitrogen gas, or the like.

The first hydrophilizing apparatus 38 hydrophilizes the bonding surface CPa of the chip CP with the chip CP being held by the second chip carrier SC. For example, the first hydrophilizing apparatus 38 supplies pure water (e.g., deionized water) onto the chip CP while rotating the second chip carrier SC held on a spin chuck. The pure water imparts OH groups to the bonding surface CPa of the chip CP activated in advance. By using hydrogen bonding between these OH groups, the chip CP and the substrate W can be bonded.

The inverting apparatus 39 inverts the second chip carrier SC upside down, with the chip CP being held by the second chip carrier SC. The plurality of chips CP can be turned upside down at once, so that the bonding surface CPa of each chip CP can be made to face downwards. The inverting apparatus 39 may be provided inside the bonding apparatus 42.

The second activating apparatus 40 activates the bonding surface Wa of the substrate W. The second activating apparatus 40 is, for example, a plasma processing apparatus. For example, in the second activating apparatus 40, an oxygen gas, which is a processing gas, is excited into plasma under a compressed pressure to be ionized. By irradiating the bonding surface Wa of the substrate W with oxygen ions, the bonding surface Wa of the substrate W is activated. The processing gas is not limited to the oxygen gas, and may be, by way of example, a nitrogen gas, or the like.

The second hydrophilizing apparatus 41 hydrophilizes the bonding surface Wa of the substrate W. By way of example, the second hydrophilizing apparatus 41 supplies pure water (e.g., deionized water) onto the substrate W, while rotating the substrate W held on a spin chuck. The pure water imparts OH groups to the bonding surface Wa of the substrate W activated in advance. By utilizing hydrogen bonding between these OH groups, the chip CP and the substrate W can be bonded.

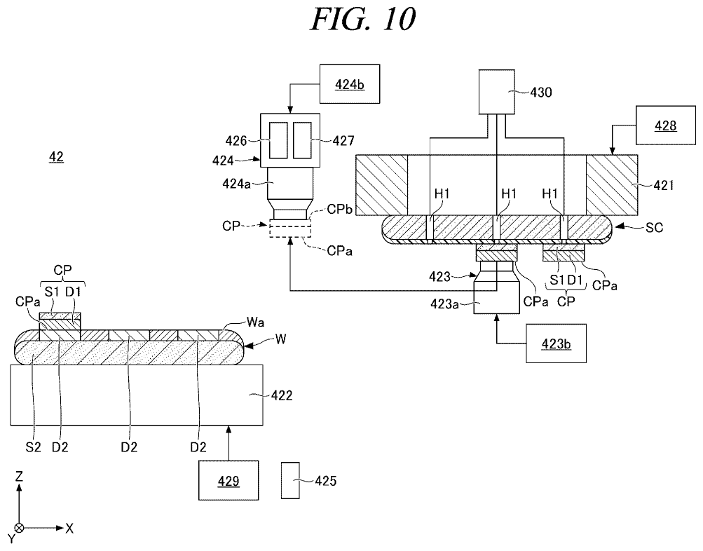

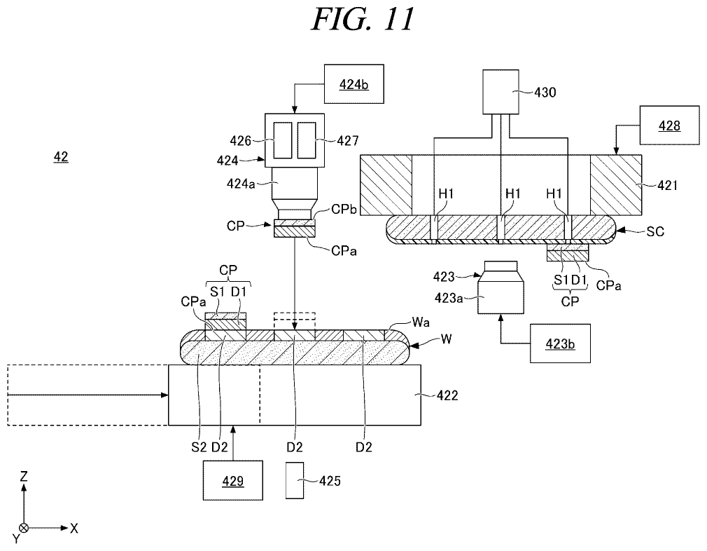

The bonding apparatus 42 separates the chip CP from the second chip carrier SC, and bonds the chip CP to the substrate W, allowing the bonding surface CPa of the separated chip CP to face the bonding surface Wa of the substrate W, as shown in FIG. 10 and FIG. 11. As a result, the chip-attached substrate CW is obtained. The device D1 of the chip CP and the device D2 of the substrate W are electrically connected. Details of this bonding apparatus 42 will be described later.

The control circuit 9 is, by way of non-limiting example, a computer, and includes a processor 91 such as a central processing unit (CPU), and a storage 92 such as a memory. The storage 92 stores a program that controls various processes performed in the bonding system 1. The control circuit 9 controls an operation of the bonding system 1 by causing the processor 91 to execute the program stored in the storage 92. For each apparatus constituting the bonding system 1, a lower-level control circuit for controlling an operation of that apparatus may be provided, and a higher-level control circuit for collectively controlling the multiple subordinate control circuits may be further provided. The lower-level control circuits and the upper-level control circuit may constitute the control circuit 9.

The control circuit 9 includes an electronic circuit such as a CPU, a field programmable gate array (FPGA), or an application specific integrated circuit (ASIC), and performs various control operations described in the present specification either by executing instruction codes stored in the memory, or by being designed as a dedicated circuit for a special purpose.

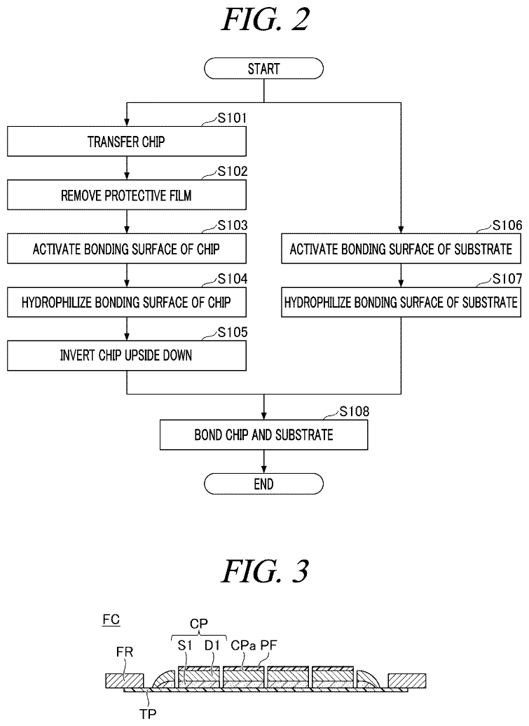

Now, with reference to FIG. 2, a bonding method according to the exemplary embodiment will be described. A processing described in FIG. 2 is performed under the control of the control circuit 9.

First, the first chip carrier transfer arm 22 takes out the chips CP together with the first chip carrier FC from the cassette C1, and transfers them to the transition device 25. Then, the first chip carrier transfer arm 32 takes out the chips CP together with the first chip carrier FC from the transition device 25, and transfers them to the chip arranging apparatus 35.

Also, the second chip carrier transfer arm 23 takes out the second chip carrier SC from the cassette C3, and transfers it to the transition device 25. Then, the second chip carrier transfer arm 33 takes out the second chip carrier SC from the transition device 25, and transfers it to the chip arranging apparatus 35.

Next, the chip arranging apparatus 35 transfers the chips CP from the first chip carrier FC onto the second chip carrier SC (process S101). Thereafter, the second chip carrier transfer arm 33 takes out the chips CP together with the second chip carrier SC from the chip arranging apparatus 35, and transfers them to the cleaning apparatus 36.

Thereafter, with the chips CP held by the second chip carrier SC, the cleaning apparatus 36 removes the protective film PF from the chips CP (process S102). Thereafter, the second chip carrier transfer arm 33 takes out the chips CP together with the second chip carrier SC from the cleaning apparatus 36, and transfers them to the first activating apparatus 37.

Then, with the chips CP held by the second chip carrier SC, the first activating apparatus 37 activates the bonding surfaces CPa of the chips CP (process S103). Thereafter, the second chip carrier transfer arm 33 takes out the chips CP together with the second chip carrier SC from the first activating apparatus 37, and transfers them to the first hydrophilizing apparatus 38.

Next, with the chips CP held by the second chip carrier SC, the first hydrophilizing apparatus 38 hydrophilizes the bonding surfaces CPa of the chips CP (process S104). Thereafter, the second chip carrier transfer arm 33 takes out the chips CP together with the second chip carrier SC from the first hydrophilizing apparatus 38, and transfers them to the inverting apparatus 39.

Next, with the chips CP held by the second chip carrier SC, the inverting apparatus 39 inverts the second chip carrier SC upside down (process S105). Thereafter, the second chip carrier transfer arm 33 takes out the chips CP together with the second chip carrier SC from the inverting apparatus 39, and transfers them to the bonding apparatus 42.

In parallel with the above-described processes S101 to S105, the following processes S106 and S107 are performed. First, the substrate transfer arm 24 takes out the substrate W from the cassette C5 and transfers it to the transition device 25. Thereafter, the substrate transfer arm 34 takes out the substrate W from the transition device 25 and transfers it to the second activating apparatus 40.

Next, the second activating apparatus 40 activates the bonding surface Wa of the substrate W (process S106). Thereafter, the substrate transfer arm 34 takes out the substrate W from the second activating apparatus 40 and transfers it to the second hydrophilizing apparatus 41.

Subsequently, the second hydrophilizing apparatus 41 hydrophilizes the bonding surface Wa of the substrate W (process S107). Thereafter, the substrate transfer arm 34 takes out the substrate W from the second hydrophilizing apparatus 41 and transfers it to the bonding apparatus 42.

Next, the bonding apparatus 42 separates the chips CP from the second chip carrier SC, and bonds the separated chips CP to the substrate W, allowing the bonding surfaces CPa of the chips CP to face the bonding surface Wa of the substrate W (process S108). As a result, the chip-attached substrate CW is obtained. The chip-attached substrate CW may be heated by a non-illustrated annealing apparatus (not shown) to improve the bonding strength between the chips CP and the substrate W.

Thereafter, the substrate transfer arm 34 takes out the chip-attached substrate CW from the bonding apparatus 42, and transfers it to the transition device 25. Finally, the substrate transfer arm 24 takes out the chip-attached substrate CW from the transition device 25 and stores it in the cassette C6. The chip-attached substrate CW is carried out from the bonding system 1 while being stored in the cassette C6.

Furthermore, after the above-described process S108, the second chip carrier transfer arm 33 takes out the second chip carrier SC from the bonding apparatus 42 and transfers it to the transition device 25. Thereafter, the second chip carrier transfer arm 23 takes out the second chip carrier SC from the transition device 25 and stores it in the cassette C4.

In addition, after the above-described process S101, the first chip carrier transfer arm 32 takes out the first chip carrier FC from the chip arranging apparatus 35 and transfers it to the transition device 25. Thereafter, the first chip carrier transfer arm 22 takes out the first chip carrier FC from the transition device 25 and stores it in the cassette C2.

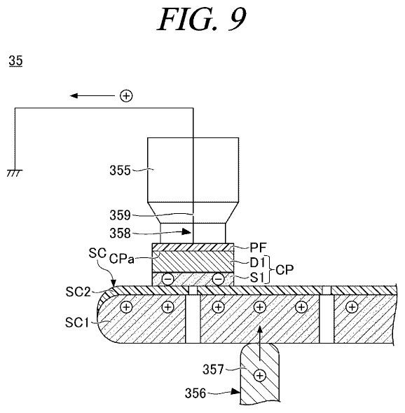

Now, referring to FIG. 8 and FIG. 9, details of the chip arranging apparatus 35 and the second chip carrier SC will be discussed. The chip arranging apparatus 35 transfers the chip CP from the first chip carrier FC onto the second chip carrier SC, as shown in FIG. 8. Thus, it is possible to use a chip carrier with relatively high durability when modifying the bonding surface CPa.

The second chip carrier SC is not particularly limited as long as it has higher durability than the first chip carrier FC. By way of example, the second chip carrier SC may be an electrostatic carrier. The electrostatic carrier includes, for example, a conductive substrate SC1 and an insulating film SC2, and electrostatically attracts the chip CP on its side opposite the conductive substrate SC1 with the insulating film SC2 therebetween.

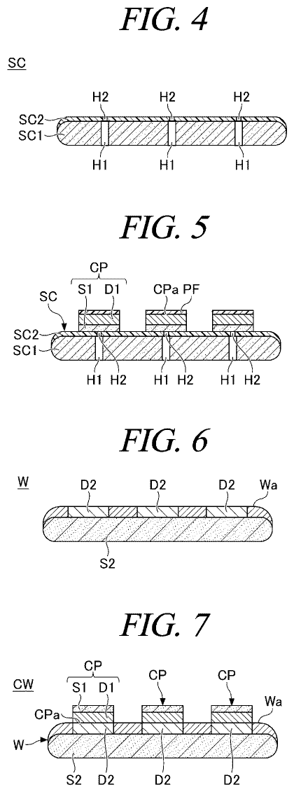

The conductive substrate SC1 is made of, for example, silicon, aluminum, an aluminum alloy, stainless steel, or titanium. As illustrated in FIG. 4 and FIG. 5, the conductive substrate SC1 may be provided with one or more through holes H1 for each chip CP. By supplying a gas into the through hole H1 or inserting a non-illustrated pin into the through hole H1, the chip CP may be separated from the second chip carrier SC. The number and arrangement of the through holes H1 may not be particularly limited.

As shown in FIG. 9, the insulating film SC2 maintains an electrostatic attracting force by restricting movement of electric charges between the base substrate S1 of the chip CP and the conductive substrate SC1. The insulating film SC2 desirably has a dielectric breakdown voltage of 30 kV or more, and more desirably, 40 kV or more.

The insulating film SC2 is desirably made of a flexible material, specifically a material having an elastic modulus of 2 GPa or less, more desirably 0.5 GPa or less. From the viewpoint of durability in the modification of the bonding surface CPa, polyimide or EVA (ethylene-vinyl acetate copolymer) is used, for example. The thickness of the insulating film SC2 is, for example, 10 μm.

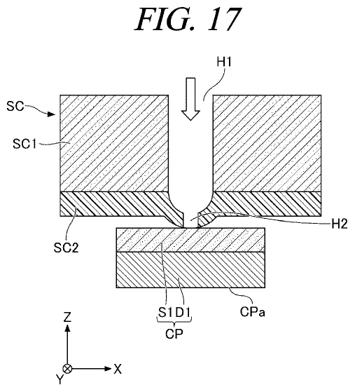

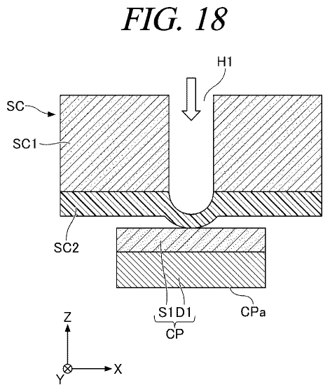

The insulating film SC2 may be provided with a through hole H2 that communicates with the through hole H1 of the conductive substrate SC1. As illustrated in FIG. 17, the diameter of the through hole H2 of the insulating film SC2 is desirably smaller than the diameter of the through hole H1 of the conductive substrate SC1. Furthermore, as shown in FIG. 18, the through hole H2 may be omitted.

It is desirable that the second chip carrier SC has the same diameter as the substrate W. In this case, the same product number (i.e., identical in dimensions and shape) can be used for both the second chip carrier transfer arm 23 and the substrate transfer arm 24, thereby reducing costs. Likewise, the same product number can be used for the second chip carrier transfer arm 33 and the substrate transfer arm 34, the first activating apparatus 37 and the second activating apparatus 40, or the first hydrophilizing apparatus 38 and the second hydrophilizing apparatus 41, thereby reducing costs. Besides, enlargement of the apparatus can also be suppressed.

As shown in FIG. 8, the chip arranging apparatus 35 includes a first chip carrier holder 351, a pressing member 352 a second chip carrier holder 353, and a chip transfer mechanism 354. The first chip carrier holder 351 holds the first chip carrier FC from below the first chip carrier FC. The first chip carrier FC holds the chip CP with the bonding surface CPa of the chip CP facing upwards. The first chip carrier holder 351 holds the frame FR of the first chip carrier FC and allows deformation of the tape TP in the opening of the frame FR.

The pressing member 352 locally presses the chip CP via the tape TP to locally deform the tape TP. The chips CP can be pushed up individually, so when picking up the chip CP, the chip CP can be suppressed from being rubbed against another chip CP. The pressing member 352 and the first chip carrier holder 351 are configured to be movable relative to each other, so that the position at which the chip CP is pushed up can be changed.

The second chip carrier holder 353 holds the second chip carrier SC from below the second chip carrier SC. The second chip carrier SC holds the chip CP with the bonding surface CPa of the chip CP facing upwards. Likewise, the first chip carrier FC also holds the chip CP with the bonding surface CPa of the chip CP facing upwards. Accordingly, the chip transfer mechanism 354 also transfers the chip CP with the bonding surface CPa of the chip CP facing upwards. The chip transfer mechanism 354 does not invert the chip CP upside down.

The chip transfer mechanism 354 includes a suction head 355 for attracting the chip CP. The suction head 355 is disposed above the chip CP. The bonding surface CPa of the chip CP is covered with the protective film PF, and the suction head 355 attracts the chip CP via the protective film PF. The suction head 355 comes into contact with the protective film PF but not with the chip CP. Therefore, damage to the chip CP can be suppressed.

As depicted in FIG. 9, the chip arranging apparatus 35 includes a charge supply 356 and a charge remover 358. The charge supply 356 applies a voltage to the conductive substrate SC1, thereby supplying electric charges of a first polarity (e.g., a positive polarity). The charge remover 358 removes the electric charges of the first polarity from the chip CP, thereby leaving in the chip CP electric charges of a second polarity (e.g., a negative polarity) which is opposite to the first polarity.

The electric charges of the first polarity are accumulated in the conductive substrate SC1, while the electric charges of the second polarity are accumulated in the chip CP. As a result, a potential difference is generated between the conductive substrate SC1 and the chip CP with the insulating film SC2 therebetween, resulting in generation of an electrostatic attracting force. The generated electrostatic attracting force is maintained even after the application of the voltage to the conductive substrate SC1 and the removal of the electric charges from the chip CP are released.

The charge supply 356 includes, for example, a power feed pin 357 configured to be brought into contact with the conductive substrate SC1. The power feed pin 357 is provided in, for example, the second chip carrier holder 353, and is electrically connected to a non-illustrated power source. The charge remover 358 includes, for example, a ground wire 359. The ground wire 359 removes the electric charges of the first polarity from the chip CP via the protective film PF, for example.

The ground wire 359 is embedded in the suction head 355 in the present exemplary embodiment, but it may be provided separately from the suction head 355. In the present exemplary embodiment, the chips CP are electrostatically attracted one by one, but after arranging multiple chips CP on the insulating film SC2, the multiple chips CP may be electrostatically attracted simultaneously.

As stated above, the insulating film SC2 is made of the flexible material. When the chip CP is pressed against the insulating film SC2 by the electrostatic attracting force, the insulating film SC2 is deformed to allow air to escape from between the chip CP and the insulating film SC2, thereby generating a vacuum attracting force between the chip CP and the insulating film SC2.

Even if the electric charges leak from the conductive substrate SC1 or the chip CP so the electric attracting force is lost, the multiple chips CP can still be held due to the vacuum attracting force. The leakage of the electric charges may occur due to, by way of example, a supply of a processing liquid to the chip CP during the removal of the protective film PF or the modification of the bonding surface CPa.

Further, although the second chip carrier SC is configured as the electrostatic carrier including the conductive substrate SC1 and the insulating film SC2 in the present exemplary embodiment, it may not be the electrostatic carrier. Although not shown, the second chip carrier SC may include a carrier substrate, and a resin film provided on a surface of the carrier substrate facing the chip CP. The second chip carrier SC holds the chips CP on the resin film. By pressing the chip CP against the resin film, the resin film can be deformed to allow a gas to be released from between the chip CP and the resin film, thereby allowing the chip CP to be vacuum-attracted onto the resin film.

The carrier substrate may have a conductive property, like the conductive substrate SC1, or, unlike the conductive substrate SC1, may have an insulating property. The carrier substrate is desirably made of a rigid material. For example, the carrier substrate is desirably made of silicon (Si), ceramic, aluminum, an aluminum alloy, stainless steel, zirconia, silicon carbide (SIC), titanium, or glass. The carrier substrate may have a diameter approximately equal to that of the substrate W. In addition, the carrier substrate may have a thickness approximately equal to that of the substrate W. The carrier substrate may have a through hole H1, the same as the conductive substrate SC1.

The resin film may have an insulating property, like the insulating film SC2, or, unlike the insulating film SC2, may have a conductive property. The resin film is desirably made of a flexible material, specifically, a material having an elastic modulus of 2 GPa or less, more desirably, 0.5 GPa or less. From the viewpoint of durability in modifying the bonding surface of the chip CP, it is desirable that the resin film is made of, by way of non-limiting example, polyimide or EVA (ethylene-vinyl acetate copolymer). The thickness of the resin film is, for example, 10 μm. In addition, the resin film may be single layered or multi-layered. For example, the resin film may have a polyolefin layer and an acrylic adhesive layer. Like the insulating film SC2, the resin film may have a through hole H2.

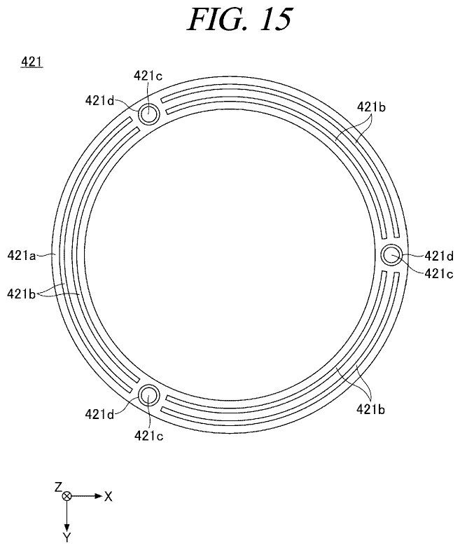

Now, referring to FIG. 10 to FIG. 18, details of the bonding apparatus 42 will be described. As illustrated in FIG. 10 and FIG. 11, the bonding apparatus 42 separates the chip CP from the second chip carrier SC, and bonds the separated chip CP to the substrate W with the bonding surface CPa of the chip CP facing the bonding surface Wa of the substrate W. As a result, the chip-attached substrate CW is obtained. The device D1 of the chip CP and the device D2 of the substrate W are electrically connected.

The bonding apparatus 42 includes, for example, a chip carrier holder 421, a substrate holder 422, a first chip transfer mechanism 423, and a second chip transfer mechanism 424. The chip carrier holder 421 holds the second chip carrier SC from above the second chip carrier SC with the bonding surface CPa of each of the plurality of chips CP held on the second chip carrier SC facing downwards. The substrate holder 422 holds the substrate W from below the substrate W with the bonding surface Wa of the substrate W facing upwards. The first chip transfer mechanism 423 receives the chip CP from the second chip carrier SC and transfers the chip CP with the bonding surface CPa of the chip CP facing downwards. The second chip transfer mechanism 424 receives the chip CP from the first chip transfer mechanism 423, and bonds the received chip CP to the substrate W, allowing the bonding surface CPa of the chip CP to face downwards.

According to the present exemplary embodiment, before the chip carrier holder 421 holds the second chip carrier SC, the inverting apparatus 39 inverts the second chip carrier SC upside down. The plurality of chips CP can be inverted upside down all at once in advance so that the bonding surface CPa of each chip CP faces downwards. The first chip transfer mechanism 423 and the second chip transfer mechanism 424 do not individually invert the chips CP upside down while individually transferring the chips CP. Since a mechanism for individually inverting the chips CP upside down can be omitted, particle generation from that mechanism can be suppressed. In addition, the structures of the first chip transfer mechanism 423 and the second chip transfer mechanism 424 can be simplified. Besides, the number of inversions can be reduced, so that the particle generation and the throughput can be improved.

According to the present exemplary embodiment, the chip carrier holder 421 holds the second chip carrier SC from above the second chip carrier SC, and the substrate holder 422 holds the substrate W from below the substrate W. By holding the substrate W, which is larger than the chip CP and heavier than the chip C, from below the substrate W, the substrate W can be stably held, and the chip CP can be bonded to a required position on the substrate W. The accuracy of the bonding position is mainly determined by the accuracy of positional alignment between the second chip transfer mechanism 424 and the substrate holder 422. As compared to this positional alignment accuracy, the positional alignment accuracy between the first chip transfer mechanism 423 and the chip carrier holder 421 may be lower. Therefore, even if the chip carrier holder 421 holds the second chip carrier SC from above the second chip carrier SC, the accuracy of the bonding position is not degraded.

Furthermore, although the chip carrier holder 421 holds the second chip carrier SC in the present exemplary embodiment, it may hold the first chip carrier FC. If the bonding system 1 does not modify the bonding surface CPa of the chip CP, there is no need to transfer the chip CP from the first chip carrier FC onto the second chip carrier SC. Therefore, the chip carrier holder 421 may hold the first chip carrier FC.

If the chip carrier holder 421 holds the first chip carrier FC, the inverting apparatus 39 may invert the first chip carrier FC upside down. The plurality of chips CP can be turned upside down in advance, so that the bonding surface CPa of each chip CP can be made to face downwards. Since a mechanism for individually inverting the chips CP upside down can be omitted, the particle generation from that mechanism can be suppressed. In addition, the structures of the first chip transfer mechanism 423 and the second chip transfer mechanism 424 can be simplified. Besides, the number of inversions can be reduced, so that the particle generation and the throughput can be improved. Moreover, the accuracy of the bonding position between the chip CP and the substrate W can also be improved.

The first chip transfer mechanism 423 includes, for example, a first suction head 423a and a first driver 423b. The first suction head 423a is disposed under the chip CP and attracts the bonding surface CPa of the chip CP. For example, the first suction head 423a is movable in the X-axis direction and the Z-axis direction. The first driver 423b moves the first suction head 423a.

Desirably, the first suction head 423a attracts the bonding surface CPa of the chip CP in a non-contact manner. That is, it is desirable that the first suction head 423a attracts the bonding surface CPa of the chip CP in a state where a gap is formed between the first suction head 423a and the chip CP. This suppresses contamination of the bonding surface CPa of the chip CP. The first suction head 423a is of, for example, an ultrasonic or Bernoulli type. The ultrasonic type utilizes the squeeze effect due to ultrasonic vibration, and the Bernoulli type utilizes the Bernoulli effect. The ultrasonic type can suppress an error in a horizontal direction, as compared to the Bernoulli type.

The second chip transfer mechanism 424 includes, for example, a second suction head 424a and a second driver 424b. The second suction head 424a is disposed above the chip CP and attracts the rear surface CPb opposite to the bonding surface CPa of the chip CP. Since contamination of the rear surface CPb is not problematic, the second suction head 424a is configured to come into contact with the chip CP.

For example, the second suction head 424a is movable in the X-axis direction, the Y-axis direction, the Z-axis direction, and the θ direction. Here, the θ direction is a circumferential direction around a vertical rotation center line. That is, the second suction head 424a may be rotated around the vertical rotation center line. The second driver 424b moves the second suction head 424a.

As shown in FIG. 10 and FIG. 11, the bonding apparatus 42 may be equipped with at least one of a first imager 425, a second imager 426, and a third imager 427 in order to improve the accuracy of the bonding position between the chip CP and the substrate W. Further, the first imager 425, the second imager 426, and the third imager 427 may not need to acquire an image each time the chip CP and the substrate W are bonded, but may acquire images periodically.

As illustrated in FIG. 10, the first imager 425 images an alignment mark on the bonding surface CPa of the chip CP held by the second suction head 424a. Although the number of alignment marks to be imaged is not particularly limited, it may be two, for example. The alignment mark may be a dedicated mark, or may be a part of an electric circuit constituting the device D1.

The first imager 425 is positioned below the second suction head 424a. The first imager 425 transmits the acquired image to the control circuit 9. The control circuit 9 detects the position of the chip CP in a first coordinate system set in the second suction head 424a by performing an image processing on the image acquired by the first imager 425.

As illustrated in FIG. 11, the second imager 426 images an alignment mark on the bonding surface Wa of the substrate W held by the substrate holder 422. Although the number of alignment marks to be imaged is not particularly limited, it may be two, for example. The alignment mark may be a dedicated mark, or may be a part of an electric circuit constituting the device D2.

The second imager 426 is disposed above the substrate holder 422 and is provided at the second suction head 424a, for example. The second imager 426 transmits the acquired image to the control circuit 9. The control circuit 9 detects the position of the device D2 in a second coordinate system set in the substrate holder 422 by performing an image processing on the image acquired by the second imager 426.

The control circuit 9 aligns the positions of the chip CP held by the second suction head 424a and the substrate W held by the substrate holder 422 by using the image acquired by at least one of the first imager 425 and the second imager 426. Before bonding the chip CP and the substrate W, the position of the chip CP or the substrate W can be corrected, so that the accuracy of the bonding position can be improved.

The third imager 427 images both the alignment mark of the bonding surface CPa of the chip CP and the alignment mark of the bonding surface Wa of the substrate W simultaneously after the chip CP is bonded to the substrate W. The third imager 427 images the alignment marks of the chip CP and the substrate W through the chip CP or the substrate W (the chip CP in the present exemplary embodiment). The third imager 427 is configured as, for example, an infrared camera.

When imaging the alignment marks of the chip CP and the substrate W through the chip CP, the third imager 427 is positioned above the substrate holder 422 and is provided at the second suction head 424a, for example. The third imager 427 transmits the acquired image to the control circuit 9. The control circuit 9 detects an error between an actual bonding position and a target bonding position by performing an image processing on the image acquired by the third imager 427.

By using the image acquired by the third imager 427, the control circuit 9 aligns the positions of the chip CP held by the second suction head 424a and the substrate W held by the substrate holder 422 in the subsequent bonding of the chip CP and the substrate W. The position of the chip CP or the substrate W can be corrected by taking into account the characteristics of the bonding apparatus 42, etc., so that the accuracy of the bonding position can be improved.

As shown in FIG. 10 and FIG. 11, the bonding apparatus 42 may include a first mover 428 and a second mover 429. The first mover 428 moves the chip carrier holder 421 horizontally. The first mover 428 may move the chip carrier holder 421 vertically. The second mover 429 moves the substrate holder 422 horizontally. The second mover 429 may move the substrate holder 422 vertically.

According to the present exemplary embodiment, the chip carrier holder 421 holds the second chip carrier SC from above the second chip carrier SC, and the substrate holder 422 holds the substrate W from below the substrate W. Therefore, it is possible to locate the second chip carrier SC and the substrate W at different heights. Accordingly, it is possible to locate the chip carrier holder 421 and the substrate holder 422 at different heights.

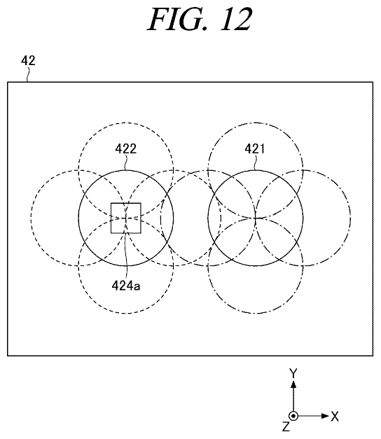

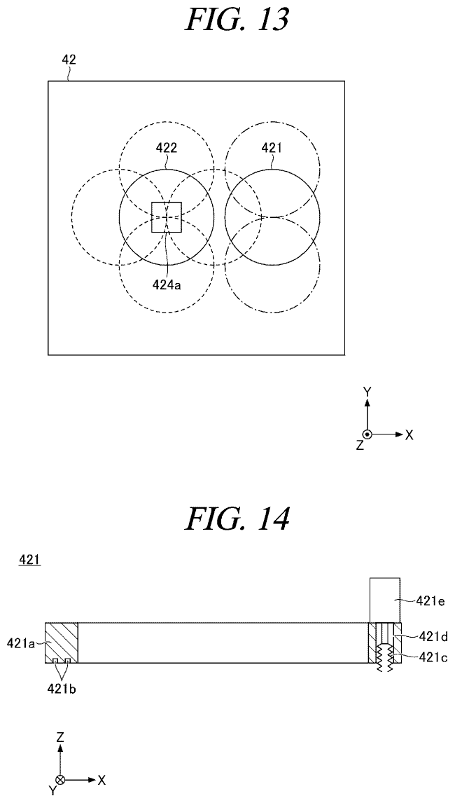

As a result, as shown in FIG. 12 and FIG. 13, when the chip carrier holder 421 is viewed from above, a movement range of the chip carrier holder 421 (the range indicated by a dashed dotted line in FIG. 12 and FIG. 13) and a movement range of the substrate holder 422 (the range indicated by a dashed line in FIG. 12 and FIG. 13) can overlap. This makes it possible to reduce the footprint of the bonding apparatus 42.

The substrate holder 422 is movable in a first axis direction that is horizontal and a second axis direction that is horizontal and orthogonal to the first axis direction. The first axis direction is, for example, the X-axis direction, and the second axis direction is, for example, the Y-axis direction. The substrate holder 422 is movable in both the positive X-axis direction and the negative X-axis direction. Also, the substrate holder 422 is movable in both the positive Y-axis direction and the positive Y-axis direction.

The chip carrier holder 421 may be movable in both the first axis direction and the second axis directions as shown in FIG. 12, or may be movable only in the second axis direction between the first and second axis directions as shown in FIG. 13. In the latter case, as shown in FIG. 13, when the chip carrier holder 421 is viewed from above, the movement range of the chip carrier holder 421 and the movement range of the substrate holder 422 may overlap in the first axis direction. In the latter case, the footprint of the bonding apparatus 42 can be made smaller than in the former case.

As illustrated in FIG. 10 and FIG. 11, the bonding apparatus 42 may be equipped with a pressing mechanism 430. The pressing mechanism 430 presses the chip CP downwards against the second chip carrier SC held by the chip carrier holder 421. The pressing mechanism 430 individually presses the chips CP downwards, thereby separating the chips CP from the second chip carrier SC individually.

The pressing mechanism 430 separates the chip CP from the second chip carrier SC by, for example, supplying a gas into the through hole H1 of the conductive substrate SC1 or inserting a non-illustrated pin into that through hole H1. The number and arrangement of the through holes H1 may not be particularly limited. The insulating film SC2 may be provided with the through hole H2 as shown in FIG. 17, or may not be provided with the through hole H2 as shown in FIG. 18.

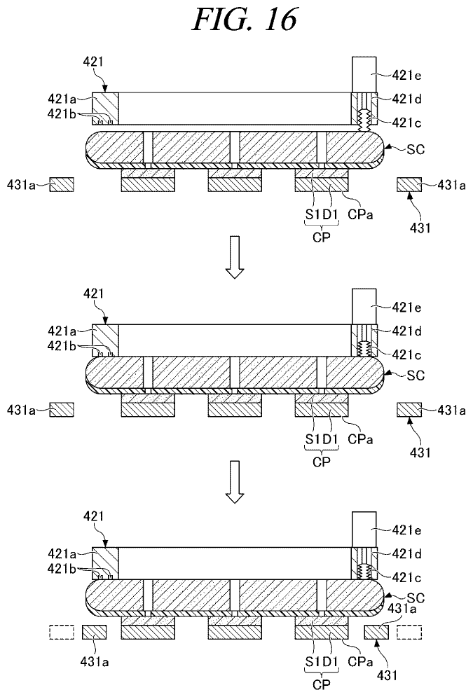

As depicted in FIG. 16, the chip carrier holder 421 may attract only a portion of a top surface of the second chip carrier SC. The pressing mechanism 430 is able to press the chip CP downwards on the remaining portion of the top surface of the second chip carrier SC. Therefore, while holding the second chip carrier SC from above the second chip carrier SC, the chip CP held on the second chip carrier SC can be pressed downwards.

The chip carrier holder 421 includes, by way of example, a ring member 421a. The ring member 421a attracts an outer peripheral portion of the top surface of the second chip carrier SC. The pressing mechanism 430 can press down the chip CP at a central portion of the top surface of the second chip carrier SC. For example, a groove 421b for vacuum attraction is formed in a bottom surface of the ring member 421a. Instead of the groove 421b, a hole may be formed.

In addition, although not illustrated, the chip carrier holder 421 may have a second ring member concentric with the ring member 421a inside the ring member 421a. Furthermore, the chip carrier holder 421 may have a radial or lattice-shaped rib portion inside the ring member 421a. The second ring member and the rib portion may be provided in combination. Any of various configurations may be adopted as long as the pressing mechanism 430 is capable of pressing down the chip CP.

The chip carrier holder 421 may have pad members 421c. The pad members 421c are provided at an interval therebetween along an outer periphery of the top surface of the second chip carrier SC. Like the ring member 421a, the pad members 421c attract the outer peripheral portion of the top surface of the second chip carrier SC. Therefore, the pressing mechanism 430 can press the chip CP downwards at the central portion of the top surface of the second chip carrier SC.

When the ring member 421a and the pad members 421c are used in combination, through holes 421d are formed in the ring member 421a, and the pad members 421c are disposed in this through holes 421d. Instead of the through hole 421d, a notch may be formed. In addition, although the ring member 421a and the pad members 421c are used in combination in the present exemplary embodiment, either one of them may be used alone.

The pad member 421c may be expanded and contracted vertically. In the present exemplary embodiment, the pad member 421c has a bellows structure, but it may be a telescopic. As shown in FIG. 16, after attracting the top surface of the second chip carrier SC, the pad member 421 contracts, allowing the ring member 421a to attract the top surface of the second chip carrier SC. This allows the second chip carrier SC to be smoothly transferred between the transfer device and the ring member 421a.

The chip carrier holder 421 may have an elevating member 421e. The elevating member 421e elevates the pad member 421c relative to the ring member 421a. After the pad member 421c attracts the top surface of the second chip carrier SC, the pad member 421c is raised, allowing the ring member 421a to attract the upper surface of the second chip carrier SC. The elevating member 421e is configured as, for example, a pneumatic cylinder or an electric cylinder.

In the present exemplary embodiment, since the chip carrier holder 421 attracts only a portion of the top surface of the second chip carrier SC, the attracting force is small. Thus, as illustrated in FIG. 16, the bonding apparatus 42 may be further equipped with a drop restricting mechanism 431. The drop restricting mechanism 431 restricts the second chip carrier SC from falling down from the chip carrier holder 421.

The drop restricting mechanism 431 includes, by way of example, a plurality of movable members 431a, and a driver (not shown) that moves the plurality of movable members 431a between an open position and a closed position. The open position is a position that allows the second chip carrier SC to be raised or lowered. The closed position is a position that restricts the fall of the second chip carrier SC.

Although the chip carrier holder 421 holds the second chip carrier SC in this exemplary embodiment, it may also hold the first chip carrier FC as mentioned above. In the latter case, the ring member 421a and the pad members 421c attract the outer periphery of the first chip carrier FC, specifically, the frame FR.

So far, the exemplary embodiments of the bonding apparatus, the bonding system, and the bonding method according to the present disclosure have been described. However, the present disclosure is not limited to the above-described exemplary embodiment and the like. Various changes, modifications, replacements, additions, deletions and combinations may be made within the scope of the claims, which are all incorporated within a technical scope of the present disclosure.

This application claims priority to Japanese Patent Application No. 2023-076345, filed on May 2, 2023, which application is hereby incorporated by reference in their entirety.

### EXPLANATION OF CODES

1: Bonding system
42: Bonding apparatus
421: Chip carrier holder
422: Substrate holder
423: First chip transfer mechanism
424: Second chip transfer mechanism
CP: Chip
SC: Second chip carrier (Chip carrier)
W: Substrate

1. A bonding apparatus, comprising:
a chip carrier holder holding a chip carrier from above the chip carrier in a state that multiple chips are held by the chip carrier and a bonding surface of each of the multiple chips faces downwards;
a substrate holder holding a substrate from below the substrate in a state that a bonding surface of the substrate faces upwards;
a first chip transfer mechanism including a driver, the first chip transfer mechanism receiving the chip from the chip carrier and transferring the chip with the bonding surface of the chip facing downwards; and
a second chip transfer mechanism including a driver, the second chip transfer mechanism receiving the chip from the first chip transfer mechanism and bonding the chip to the substrate with the bonding surface of the chip facing downwards.

2. The bonding apparatus of claim 1, further comprising:
a first mover moving the chip carrier holder horizontally; and
a second mover moving the substrate holder horizontally,
wherein when the chip carrier holder is viewed from above, a movement range of the chip carrier holder and a movement range of the substrate holder overlap.

3. The bonding apparatus of claim 2,
wherein the second mover moves the substrate holder in a first axis direction and a second axis direction, the first axis direction being horizontal, and the second axis direction being orthogonal to the first axis direction,
the first mover moves the chip carrier holder only in the second axis direction between the first axis direction and the second axis direction, and
when the chip carrier holder is viewed from above, the movement range of the chip carrier holder and the movement range of the substrate holder overlap in the first axis direction.

4. The bonding apparatus of claim 1,
wherein the first chip transfer mechanism further includes a first suction head attracting the bonding surface of the chip in a non-contact manner.

5. The bonding apparatus of claim 1, further comprising:
a first imager imaging an alignment mark on the bonding surface of the chip held by the second chip transfer mechanism.

6. The bonding apparatus of claim 1, further comprising:
a second imager imaging an alignment mark on the bonding surface of the substrate held by the substrate holder.

7. The bonding apparatus of claim 1,
wherein the chip carrier is an electrostatic carrier electrostatically attracting the chip.

8. The bonding apparatus of claim 1,
wherein the chip carrier includes a tape to which the chip is attached, and a frame to which an outer periphery of the tape is attached.

9. A bonding system, comprising:
a bonding apparatus as claimed in claim 7;
a first activating apparatus activating the bonding surface of the chip with the chip held by the electrostatic carrier;
a first hydrophilizing apparatus hydrophilizing the bonding surface of the chip with the chip held by the electrostatic carrier; and
a transfer device transferring the electrostatic carrier to the first activating apparatus, the first hydrophilizing apparatus, and the bonding apparatus in this order.

10. A bonding method, comprising:
bonding, by using a bonding apparatus as claimed in claim 1, the chip and the substrate.

11. The bonding system of claim 9, wherein the first activating apparatus is a plasma processing apparatus, and
the first activating apparatus irradiates the bonding surface of the chip with oxygen ions to activate the bonding surface of the chip.

12. The bonding system of claim 11, wherein the first hydrophilizing apparatus supplies deionized water onto the chip while the chip carrier is rotated.

13. A bonding method, comprising:
holding, by a chip carrier holder, a chip carrier from above the chip carrier in a state that multiple chips are held by the chip carrier and a bonding surface of each of the multiple chips faces downwards;
holding, by a substrate holder, a substrate from below the substrate in a state that a bonding surface of the substrate faces upwards;
by a first chip transfer mechanism, receiving the chip from the chip carrier and transferring the chip with the bonding surface of the chip facing downwards; and
by a second chip transfer mechanism, receiving the chip from the first chip transfer mechanism and bonding the chip to the substrate with the bonding surface of the chip facing downwards.

14. The bonding method of claim 13, wherein the first chip transfer mechanism includes a first suction head and a first driver, and
the receiving the chip from the chip carrier includes attracting, via the first suction head, the bonding surface of the chip in a non-contact manner.

15. The bonding method of claim 14, wherein the second chip transfer mechanism includes a second suction head and a second driver, and
the receiving the chip from the first chip transfer mechanism includes attracting, via the second suction head, a rear surface of the chip opposite to the bonding surface of the chip.

16. The bonding method of claim 13, further comprising:
by a first imager, imaging an alignment mark on the bonding surface of the chip held by the second chip transfer mechanism.

17. The bonding method of claim 13, further comprising:
by a second imager, imaging an alignment mark on the bonding surface of the substrate held by the substrate holder.

18. The bonding method of claim 13, wherein the chip carrier is an electrostatic carrier that electrostatically attracts the multiple chips.

19. The bonding method of claim 13, wherein the chip carrier includes a tape to which the chip is attached, and a frame to which an outer periphery of the tape is attached.

20. A bonding system, comprising:
a chip carrier holder holding a chip carrier from above the chip carrier in a state that multiple chips are held by the chip carrier and a bonding surface of each of the multiple chips faces downwards;
a substrate holder holding a substrate from below the substrate in a state that a bonding surface of the substrate faces upwards;
a first chip transfer mechanism including a driver and receiving the chip from the chip carrier and transferring the chip with the bonding surface of the chip facing downwards;
a second chip transfer mechanism including a driver and receiving the chip from the first chip transfer mechanism and bonding the chip to the substrate with the bonding surface of the chip facing downwards;
a first activating apparatus activating the bonding surface of the chip with the chip held by the electrostatic carrier;
a first hydrophilizing apparatus hydrophilizing the bonding surface of the chip with the chip held by the electrostatic carrier; and
a transfer device transferring the electrostatic carrier to the first activating apparatus, the first hydrophilizing apparatus, and the bonding apparatus in this order, wherein
the first activating apparatus is a plasma processing apparatus,
the first activating apparatus irradiates the bonding surface of the chip with oxygen ions to activate the bonding surface of the chip, and
the first hydrophilizing apparatus supplies deionized water onto the chip while the chip carrier is rotated.
